(19) United States
(12) Patent Application Publication
(10) Pub. No.: US 2024/0213957 A1
(43) Pub. Date: Jun. 27, 2024

(54) INTEGRATED BALUN AND FILTER

(71) Applicant: Texas Instruments Incorporated, Dallas, TX (US)

(72) Inventors: Yao Yu, San Jose, CA (US); Hassan Omar Ali, Murphy, TX (US); Ting-Ta Yen, San Jose, CA (US); Swaminathan Sankaran, Allen, TX (US)

(73) Assignee: Texas Instruments Incorporated, Dallas, TX (US)

(21) Appl. No.: 18/145,497

(22) Filed: Dec. 22, 2022

(51) Int. Cl. H03H 9/54; H03H 7/42; H03H 9/00; H03H 9/02

(52) U.S. Cl. CPC H03H 9/542; H03H 7/42; H03H 9/0095; H03H 9/02133

(57) ABSTRACT

In one example, an integrated circuit comprises a filter having first and second filter terminals. The filter includes a first inductor coupled between the first and second filter terminals. The filter further includes a resonator coupled between the first and second filter terminals. A second inductor is coupled between differential terminals and is magnetically coupled to the first inductor.

### BACKGROUND

A balun performs a signal conversion between a single-ended signal and a pair of differential signals. Use of differential signaling may reduce the effect of common mode noise and increase dynamic range. However, some circuits may be configured to receive or transmit only single-ended signal. Such circuits, such as a filter, can interface with a balun to transmit or receive a single-ended signal, and the balun can perform the signal conversion. Both the balun and the interfacing circuit can add noise to the signal. Moreover, the balun and the interfacing circuit together can increase the overall system footprint and fabrication cost.

### SUMMARY

Various integrated circuits are disclosed. In one example, an integrated circuit comprises a filter having first and second filter terminals. The filter includes a first inductor coupled between the first and second filter terminals. The filter further includes a resonator coupled between the first and second filter terminals. A second inductor is coupled between differential terminals and is magnetically coupled to the first inductor.

In another example, an integrated circuit includes a semiconductor die, a first metal layer and a second metal layer. The semiconductor die includes a resonator. The first metal layer is on the semiconductor die. The first metal layer includes a terminal of the resonator. The second metal layer is on the first metal layer. The second metal layer includes an inductor.

In another example, an integrated circuit includes a first semiconductor die, a second semiconductor die and a metal layer. The first semiconductor die has a first surface. The second semiconductor die has a second surface facing the first surface. The metal layer is on the first surface. The metal layer includes an inductor and metal interconnects coupled between the first surface and the second surface.

### BRIEF DESCRIPTION OF THE DRAWINGS

FIG. 1 is a schematic illustrating a cross-sectional view of a portion of an example device capable of converting and filtering signals.

FIG. 2 is a schematic illustrating a cross-sectional view of a portion of an example IC including a balun and a filter on a same die.

FIGS. 3A and 3B are schematics illustrating a top view and a perspective view, respectively, of the example balun of FIG. 2.

FIG. 3C is a schematic illustrating an example IC including the example balun of FIG. 2.

FIG. 4 is a schematic illustrating a cross-sectional view of a portion of an example IC including a balun and a filter on a same die.

FIG. 5A is a schematic illustrating a top view of the example balun of FIG. 4.

FIG. 5B is a schematic illustrating an example IC including the example balun of FIG. 4.

FIGS. 6-9 are schematics each illustrating a respective example IC having a balun and a filter.

FIG. 10 is a graph illustrating the insertion losses as a function of quality factor Q for an example balun.

The same reference numbers or other reference designators are used in the drawings to designate the same or similar (functionally and/or structurally) features. Also, the figures are not necessarily drawn to scale.

### DETAILED DESCRIPTION

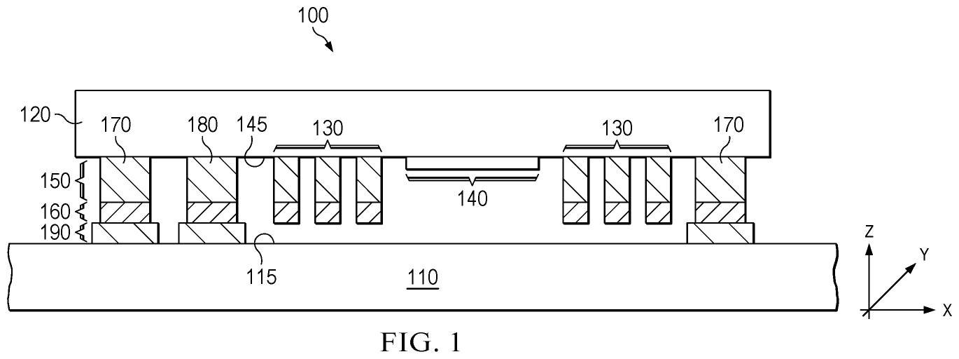

FIG. 1 illustrates a cross-sectional view of a portion of an example device 100 capable of converting and filtering wired or wireless signals (e.g., radio frequency or “RF” signals). Device 100 includes two die 110 and 120 coupled together, each having a respective stack of patterned and etched layers thereon.

Die 110 includes certain circuitry and other features, such as driver or control circuitry (not explicitly shown) configured to provide electrical signals to circuitry on die 120. Die 110 can also receive electrical signals from circuitry on die 120. A conductive layer 190 on die 110 has conductive pads, which facilitate coupling between dies 110 and 120. As used herein, the word “conductive” refers to material that allows the flow of electric current in one or more directions. Certain conductive pads of conductive layer 190 may facilitate creating an electrical interconnection between an output terminal of driver or control circuitry on die 110 and circuitry on die 120.

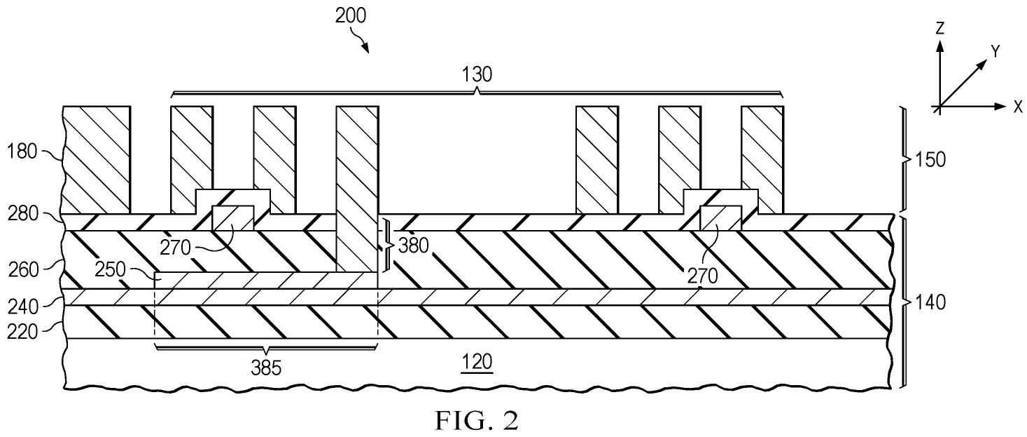

Die 120 includes certain circuitry and other features, including a balun 130, a filter 140 coupled to balun 130, a conductive layer 150 including interconnects (e.g., posts) 170 and 180, and a solder layer 160. Balun 130 and filter 140 may have respective circuitry or features within the same layer(s) of die 120, as explained further herein with reference to FIGS. 2 through 5.

In the example shown in FIG. 1, die 110 and 120 are coupled together in a flip-chip arrangement, in which die 120 is inverted or flipped relative to an orientation used to form a layered stack of material thereon (e.g., layers 150 and 160). Alternative examples may use wire bonding to form electrical interconnections between circuitry on die 110 and circuitry on die 120. In the flip-chip arrangement shown in FIG. 1, die 120 has a surface 145 facing a surface 115 of die 110. Die 110 and 120 are interconnected through posts 170 and 180 to form a cavity around certain circuitry on die 110 or 120.

A description of an example process for coupling die together in a flip-chip arrangement is provided in U.S. Pat. No. 7,790,509, assigned to Texas Instruments Inc., which is incorporated herein in its entirety. An example description of bump structures which facilitate a flip-chip coupling of two die together, one die having a BAW resonator and the other die having corresponding oscillator driver circuit, is provided in U.S. Pat. No. 10,574,184, assigned to Texas Instruments Inc., which is incorporated herein in its entirety.

A conductive layer 150 having certain patterned features extends from a surface of die 120. The patterned features of conductive layer 150 include interconnects/posts 170 and 180 and at least a portion of a balun 130. A solder layer 160 is over conductive layer 150. Solder layer 160 forms a barrier that surrounds at least filter 140, protecting it from mechanical stress and from contamination. In some examples, solder layer 160 is a continuous structure. In some examples, solder layer 160 has segmented portions. Solder layer 160) may be used, for example, in a solder reflow process to form solder joints connecting posts 170 and 180 on die 120 to corresponding conductive pads 190 of die 110.

In the illustrated example, posts 170 extending from die 120 are soldered together with corresponding conductive pads 190 on die 110, thereby forming a continuous sealing barrier that encompasses circuitry on die 120, including at least respective portions of balun 130 and filter 140. The sealing barrier may form a sealed cavity around certain stress-sensitive circuitry formed on die 120.

Post 180 provides a conductive input/output (I/O) interconnect between driver or control circuitry on die 110 and corresponding circuitry on die 120, such as respective portions of balun 130 or filter 140. Post 180 thus enables the formation of a circuit including respective circuitry on both die 110 and 120. In some examples, in addition to or in lieu of providing an I/O interconnect, post 180 forms a continuous sealing barrier that encompasses inward-facing circuitry on die 120, such as respective portions of balun 130 or filter 140. Where post 180 provides a sealing barrier, post 170 may be omitted altogether or, alternatively, conductive layer 150 may include multiple posts 170 at separate locations to enhance the structural integrity of the physical interconnection between die 110 and die 120.

The flip-chip arrangement shown in FIG. 1 facilitates packaging stress-sensitive circuitry, such balun 130 or filter 140 on die 120, together with a related semiconductor die 110. Stress-sensitive circuitry has electrical characteristics that can be adversely affected by mechanical stress. Examples include precision reference circuits, diodes, filters, sensors, resonators, and so forth. Unwanted stress on stress-sensitive circuitry may be reduced or eliminated, for example, by coupling together a first semiconductor die 110 having driver or control circuitry thereon to a second semiconductor die 120 having stress-sensitive circuitry thereon (e.g., balun 130 or filter 140).

Higher frequency baluns, such as those for wireless local area network (WLAN) applications at 2.5 GHz and 5.8 GHz frequencies, may be easier to implement on an integrated chip because of smaller inductance requirement. However, lower frequency baluns, such as those operating within the cellular band, may be more difficult to implement. Such baluns can be implemented in a single in-line package (SIP) configuration in an integrated product development (IPD) process or on a printed circuit board (PCB). See, J. Mondal, et al., “Design and Characterization of an Integrated Passive Balun for Quad Band GSM Applications,” IEEE Electronic Components and Technology Conference, pp. 534-540, 2006, incorporated herein by reference.

It is desirable to reduce the signal loss of a balun. However, certain submicron processing, such as back end-of-line (BEOL), use very thin metal layers to increase the efficiency of routing for digital applications. With continuing downscaling of process dimensions, the thickness of metals used in layer stacks continues to decrease. Such thin metals, however, have very high RF loss and poor quality factor Q. In certain situations, only one copper metal layer may be made available for power routing. An aluminum redistribution layer may also be available. Aluminum, however, has a relatively high resistivity and relatively poor electromigration characteristics. These material properties complicate designing baluns with high quality factor Q.

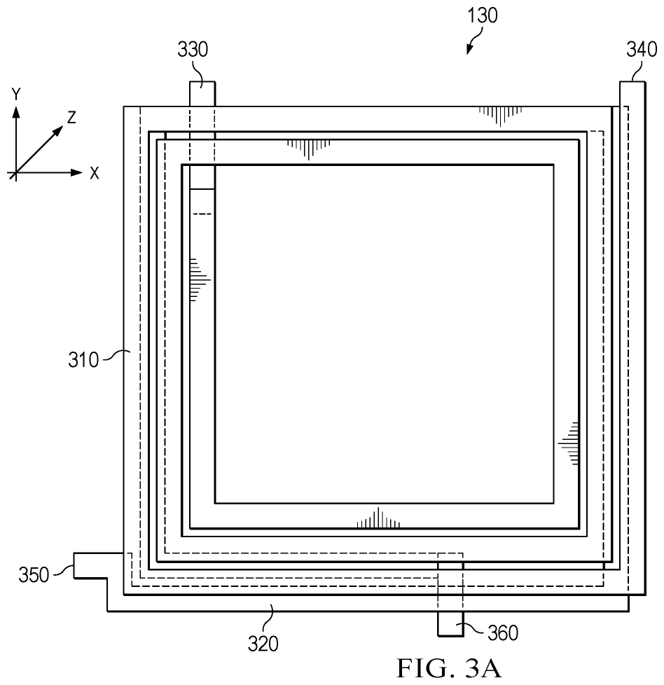

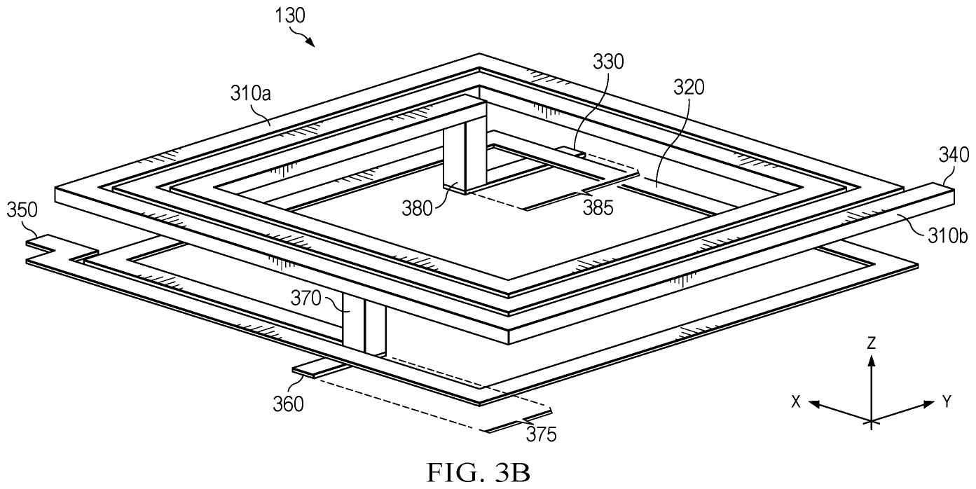

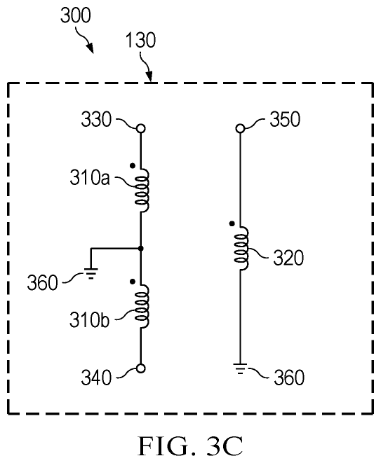

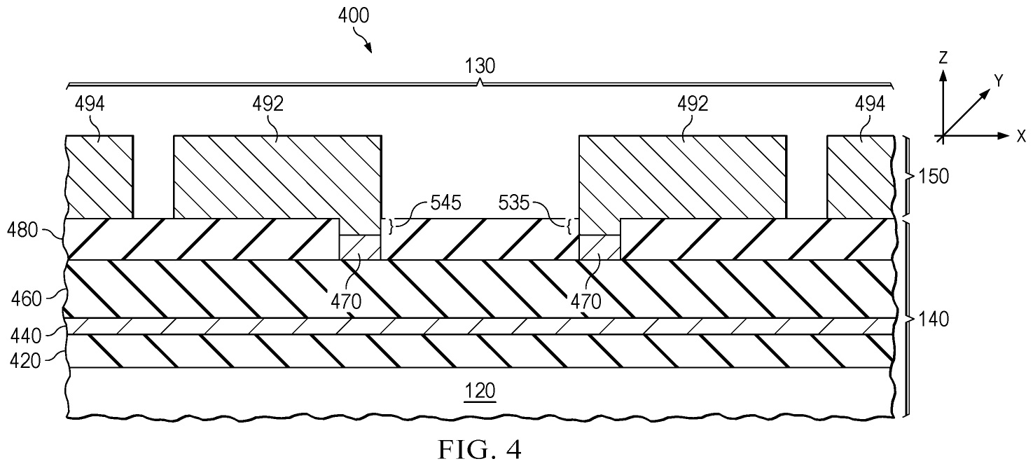

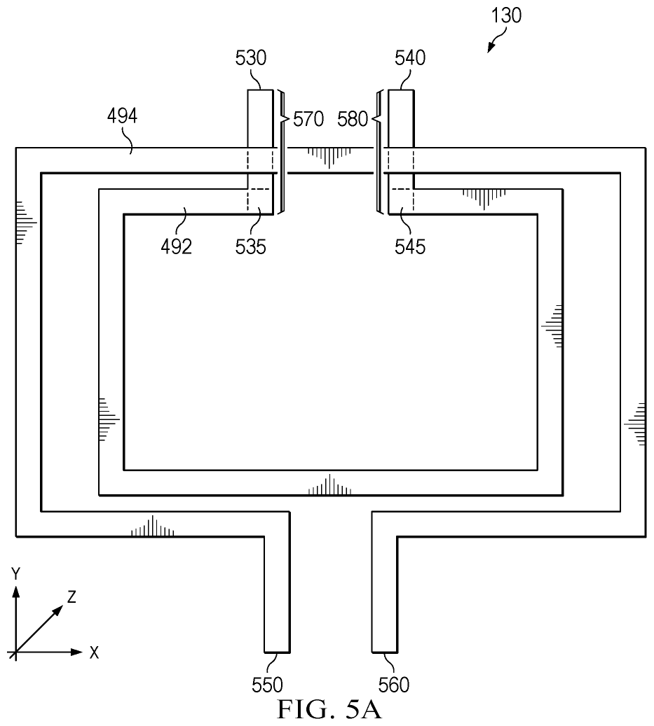

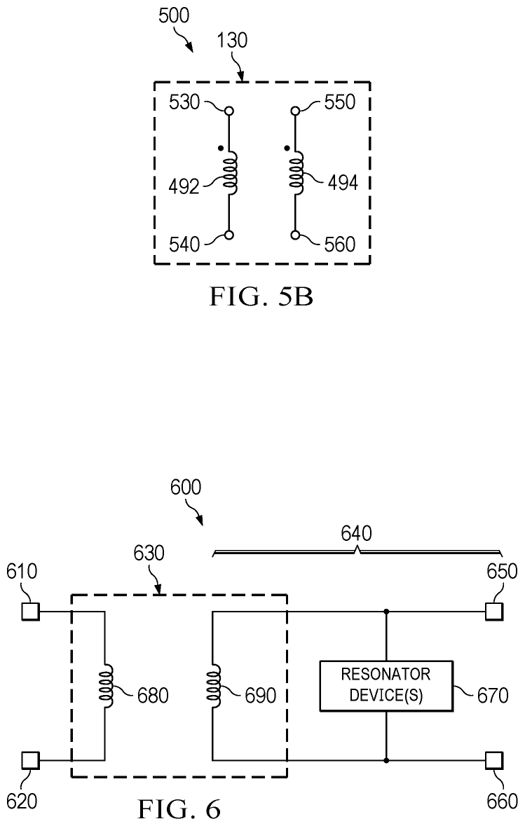

In some examples, balun 130 circuitry and filter 140 circuitry are on the same die. Such integration may be implemented, for example, using the same conductive layer 150 that is used for power routing and for flip-chip coupling die together. An example of a balun 130 having a stacked arrangement of primary and secondary coil windings of superimposed inductors is described further herein with reference to FIGS. 2, 3A and 3B. An example of a balun 130 having a coplanar arrangement of primary and secondary coil windings of respective inductors is described further herein with reference to FIGS. 4 and 5.

FIG. 2 is a cross-sectional view of a portion of an integrated circuit (IC) 200. The illustrated portion of IC 200 includes a balun 130 and a filter 140 on the same die 120. Balun 130 has an arrangement of magnetically-coupled inductors separated from one another by insulator layer 280. As used herein, the word “insulator” refers to material in which electric current does not flow freely. Filter 140 has an arrangement of one or more resonators (e.g., BAW resonators). In some examples, the inductors of balun 130 can be in the form of coil windings. In some examples, the inductors of balun 130 can be in the form of quarter wavelength transmission lines.

In this example, die 120 includes a stack of layers 220-280 and 150 thereon, in which layer 220 includes insulator material (e.g., silicon dioxide, which is commonly called “oxide”), layer 240 includes insulator material (e.g., aluminum nitride), layer 250 includes conductive material (e.g., molybdenum, which is commonly called “moly”), layer 260 includes insulator material (e.g., oxide), layer 270 includes conductive material (e.g., aluminum), layer 280 includes insulator material (e.g., silicon nitride), and layer 150 includes conductive material (e.g., copper). Interstitial layers within, between or over those shown in FIG. 2 may be included in certain examples.

As shown in FIG. 2, balun 130 includes one or more primary inductors within conductive layer 150 and one or more secondary inductors within conductive layer 270. Insulator layer 280 is between the primary and secondary inductors. In some embodiments, the primary inductor(s) within conductive layer 150 can be at least partially superimposed (e.g., along the illustrated z-axis) over the secondary inductor(s) within conductive layer 270. The primary inductor(s) can be partially superimposed, for example, if there is some lateral displacement (e.g., along the illustrated x-y plane) of a portion of the primary inductor(s) in conductive layer 150 relative to a portion of the secondary inductor(s) within conductive layer 270, as shown in FIG. 2. In some embodiments, the primary inductor(s) within conductive layer 150 can be stacked directly over secondary inductors within conductive layer 270 (e.g., along the illustrated z-axis).

Conductive layers 250 or 270 can include cross-under routings for balun 130 or portions of filter 140. As shown in FIG. 2, a conductive path in conductive layer 250 is routed underneath a portion of a secondary inductor formed in conductive layer 270. An example of conductive path is conductive path 385 to be shown in FIG. 3B. Additional details of example cross-under routings are explained further herein with reference to FIGS. 3A and 3B. Filter 140 may include one or more BAW resonators, which may be within, for example, at least one of layers 220, 240, 250, 260, 270, or 280.

Monolithically integrating a BAW filter with a magnetically coupled balun may provide multiple technical advantages, including more compact designs, lower loss, and lower cost. For example, certain examples involve efficiently fabricating respective portions of a balun and a filter at the same time, while using material and dimensions that reduce signal loss. The integration of respective portions of a balun and a filter on the same die may also improve reliability, including by mechanically isolating certain stress-sensitive circuitry. The integration may also reduce the number of metal layers required to fabricate respective portions of a balun and filter. Conductive layer 150 formed on die 120 may be significantly thicker and more conductive than the layers formed on die 110. Accordingly, integrating the balun 130 on die 120 and using conductive layer 150 to form at least a portion of balun 130 may improve the quality factor Q for balun 130 while reducing insertion loss.

FIGS. 3A and 3B are schematics illustrating a top view and a perspective view, respectively, of the example balun 130 of FIG. 2. In the examples shown in FIGS. 3A and 3B, balun 130 has a stacked arrangement of one or more primary inductors 310a and 310b at least partially superimposed over a secondary inductor 320 (e.g., along the illustrated z-axis). Primary inductors 310a and 310b are both magnetically coupled to secondary inductor 320 along the illustrated z-axis. The complete or partial superimposition between primary inductors 310a and 310b and secondary inductor 320 can reduce the footprint of the inductors and improve the magnetic coupling between the inductors.

In the examples of FIGS. 3A and 3B, primary inductors 310a and 310b and secondary inductor 320 can be in the form of coil windings or can be in the form of quarter wavelength transmission lines. Primary inductors 310a and 310b are each a patterned and etched portion of conductive layer 150. Primary inductor 310a has a conductive path extending between differential terminal 330 and reference terminal 360 (e.g., a ground terminal). Primary inductor 310b has a conductive path extending between differential terminal 340 and reference terminal 360. Secondary inductor 320 is a patterned and etched portion of conductive layer 270 and has a conductive path extending from a reference terminal 360 to single-ended terminal 350.

As shown in FIG. 3B, a first via 370 is electrically coupled between primary inductors 310a and 310b and is further electrically coupled to reference terminal 360. Via 370 may be formed, for example, by fabrication processes including a deposition, a selective pattern and an etch of conductive layer 150. A conductive path 375 between a base of via 370 and reference terminal 360 is formed in conductive layer 270 or conductive layer 250 in a direction parallel to the y-axis. A portion of secondary inductor 320 extending parallel to the illustrated x-axis is routed over or under conductive path 375. As shown in FIG. 3B, conductive path 375 can be implemented in conductive layer 250, such that secondary conductor 320 is routed in conductive layer 270 over conductive path 375. In some examples, conductive path 375 can be implemented in conductive layer 270 and a cross-under, inward from conductive path 375 and parallel to the x-axis, can be implemented in conductive layer 250.

A second via 380 is coupled between primary inductor 310a and differential terminal 330. Via 380 may be formed, for example, by fabrication processes including a deposition, a selective pattern and an etch of conductive layer 150. Via 380 is also shown in FIG. 2 conductive path 385 between via 380 and differential terminal 330 is formed in conductive layer 270 or conductive layer 250 in a direction parallel to the illustrated y-axis. A portion of secondary inductor 320 extending parallel to the illustrated x-axis is routed over or under conductive path 385. As shown in FIGS. 3A and 3B, conductive path 385 can be implemented in conductive layer 250, such that secondary conductor 320 is routed in conductive layer 270 over conductive path 385. In some examples, conductive path 385 can be implemented in conductive layer 270 and a cross-under, inward from conductive path 385 and parallel to the x-axis, can be implemented in conductive layer 250.

The stacked arrangement for balun 130 shown in FIGS. 2, 3A and 3B may be implemented using conductive layer 150 for at least a portion of primary inductor 310 and conductive layer 270 for at least a portion of secondary inductor 320. The stacked arrangement of balun 130, as shown in FIGS. 2, 3A and 3B, also provides an example in which respective circuitry of balun 130 and filter 140 may be integrally formed within the same layer(s) of the same die 120.

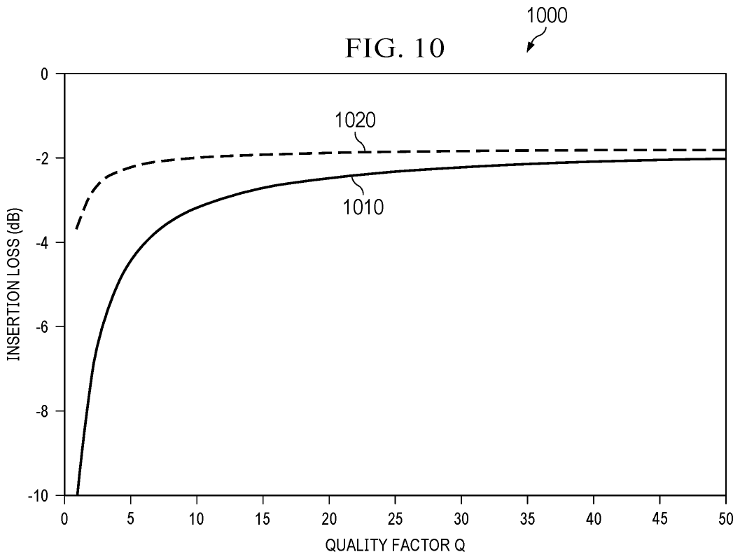

Use of a stacked arrangement, in which the primary inductor 310 the secondary inductor 320 are magnetically coupled along the illustrated z-axis, and in which primary inductor 310 is at least partially formed in conductive layer 150, may improve the quality factor Q for balun 130, while simplifying the design and reducing fabrication costs. As explained above, using a relatively thick conductive layer 150 to form at least a portion of balun 130 on die 120 may improve the quality factor Q for balun 130 while reducing insertion loss. In addition, a stacked arrangement may improve the magnetic coupling of primary and secondary inductors 310 and 320, thereby improving quality factor Q for balun 130. The description of FIG. 10 explains how the selection of materials used for the stacked arrangement may also impact the quality factor Q. As explained further with reference to the schematics shown in FIGS. 6-10, secondary inductor 320 may be a shared component of both balun 130 and filter 140, which can reduce the size/footprint of the corresponding IC, reduce signal insertion loss and the addition of noise incurred in the transmission of the signals between balun 130 and filter 140, improve bandwidth, and support the single-differential signal conversion and signal filtering operations.

FIG. 3C is a schematic illustrating an example IC 300 including the example balun 130 of FIG. 2. In this example, IC 300 includes two primary inductors 310a and 310b and a secondary inductor 320. Both primary inductors 310a and 310b are magnetically coupled to secondary inductor 320. Primary inductor 310a is coupled between reference terminal 360 (e.g., ground) and a first differential terminal 330. Primary inductor 310b is coupled between reference terminal 360 and differential terminal 340. Secondary inductor 320 is coupled between reference terminal 360 and single-ended terminal 350. In some embodiments, IC 300 is implemented using the schematics shown in FIGS. 3A and 3B.

FIG. 4 is a schematic illustrating a cross-sectional view of a portion of an example IC 400. The illustrated portion of IC 400 includes a balun 130 and a filter 140 on the same die 120, in which balun 130 has a coplanar arrangement of inductors 492 and 494 magnetically coupled (e.g., along the illustrated x-y plane). In this example, die 120 includes a stack of layers 420-480 and 150 thereon, in which layer 420 includes insulator material (e.g., oxide), layer 440 includes insulator material (e.g., aluminum nitride), layer 460 includes insulator material (e.g., oxide), layer 470 includes conductive material (e.g., aluminum), layer 480 includes insulator material (e.g., silicon nitride), and layer 150 includes conductive material (e.g., copper). Interstitial layers within, between, or over those shown in FIG. 4 may be included in certain examples.

As explained further with reference to FIG. 5A, vias 535 and 545 enable respective electrical connections between respective portions of conductive layers 150 and 470. In some examples, vias 535 and 545 are formed by selectively removing portions of insulator layer 480 (e.g., by pattern and etch processes) and forming conductive layer 150 on insulator layer 480, such that a portion of conductive layer 150 forms vias 535 and 545. In areas in which insulator layer 480 is not selectively removed, insulator layer 480 electrically separates conductive layer 150 from any underlying features of conductive layer 470.

In the example shown in FIG. 4, balun 130 has a coplanar arrangement of a primary inductor 492 and a secondary inductor 494 magnetically coupled to each other. In the illustrate coplanar arrangement, respective segments of primary inductor 492 and secondary inductor 494 are arranged side-by-side (e.g., along the illustrated x-y plane) in the same conductive layer 150. Conductive layer 470 may be used to implement cross-under routings for balun 130 and to form portions of filter 140. An example coplanar arrangement of primary and secondary inductors is described further with reference to FIGS. 5A-SB. Filter 140 may include one or more BAW resonators, which may be formed within, for example, at least one of layers 420, 440, 460, 470, or 480.

FIG. 5A illustrates a top view of the example balun 130 of FIG. 4. As shown in FIGS. 4 and 5A, balun 130 includes a secondary inductor 494 that partially or fully encompasses a primary inductor 492. Respective segments of primary inductor 492 and secondary inductor 494 are side-by-side in the same conductive layer 150 and are magnetically coupled. As shown in FIG. 5A, primary inductor 492 fully extends from differential terminal 530 to differential terminal 540. Secondary inductor 494 fully extends from terminal 550 to terminal 560. One of the terminals 550 or 560 can be configured as a reference terminal (e.g., ground), for example, and the other one of terminals 550 or 560 can be configured as a single-ended terminal.

Conductive paths 570 and 580 extend from respective ends of primary inductor 492 in a direction parallel to the illustrated y-axis. Conductive paths 570 and 580 may be formed within layer 470, for example. Conductive paths 570 and 580 enable routing both ends of primary inductor 492 under secondary inductor 494 to differential terminals 530 and 540. Via 535 provides an electrical interconnection between conductive layer 150 and an end of conductive path 570 opposite terminal 530. Via 545 provides an electrical interconnection between conductive layer 150 and an end of conductive path 580 opposite terminal 540.

The coplanar arrangement for balun 130 shown in FIGS. 4 and 5A may be implemented using a single conductive layer 150, with cross-under routing formed in layer 470. The coplanar arrangement of balun 130, as shown in FIGS. 4 and 5A, also provides an example in which respective circuitry of balun 130 and filter 140 may be integrally formed within the same layer(s) of the same die 120.

The coplanar arrangement shown in FIGS. 4 and 5A may improve quality factor Q for balun 130, while simplifying the design and minimizing fabrication costs. For example, because copper has a high conductivity, use of a single, relatively thick copper layer 150 to form both primary inductor 510 and secondary inductor 520 in a coplanar arrangement may reduce the overall resistance and thereby reduce signal insertion loss. In addition, implementing both primary inductor 510 and secondary inductor 520 in a single copper layer 150 may reduce the number of fabrication processes and thereby reduce associated costs and complexities. For example, implementing primary inductor 510 and secondary inductor 520 as part of the same copper layer 150 may facilitate efficiently forming respective portions of inductors 510 and 520) during the same process steps. As explained further with reference to the schematics shown in FIGS. 6-10, secondary inductor 494 may be a shared component of both balun 130 and filter 140, which can reduce the size/footprint of the corresponding IC, reduce signal insertion loss and the addition of noise incurred in the transmission of the signals between balun 130 and filter 140, improve bandwidth, and support the single-differential signal conversion and signal filtering operations.

FIG. 5B is a schematic illustrating an example IC 500 including the example balun 130 of FIGS. 4 and 5A. In this example, IC 500 includes a primary inductor 492 magnetically coupled to a secondary inductor 494. Primary inductor is coupled between terminals 530 and 540. Secondary inductor 494 is coupled between terminals 550 and 560. In some embodiments, IC 500 is implemented using the schematics shown in FIGS. 4 and 5A.

FIG. 6 is a schematic illustrating an IC 600 having a balun 630 and a filter 640. Balun 630 has first and second terminals 610 and 620 and first and second inductors 680 and 690 magnetically coupled to one another. Second inductor 690 can be a shared component of filter (40. The integration of inductor 690 as a shared component for balun 630 and filter 640 may be implemented, for example, by forming respective portions of balun 630 and filter 640 within the same conductive layer of an IC, as disclosed above in describing the various examples shown in FIGS. 1 through 5.

Filter 640 further includes one or more resonator devices 670 coupled between first and second terminals 650 and 660. In some examples, resonator devices 670 include BAW resonator devices. In some examples, terminals 610 and 620 are differential terminals, one of terminals 650 or 660 is a single-ended terminal and the other one of terminals 650 or 660 is a reference terminal (e.g., ground). In some examples, terminals 650 and 660 are differential terminals, one of terminals 610 or 620 is a single-ended terminal and the other one of terminals 610 or 620 is a reference terminal (e.g., ground).

The sharing of inductor 690 between filter 640 and balun 630 can reduce the size/footprint of IC 600 while supporting the single-differential signal conversion and signal filtering operations. Also, by shrinking the footprint of IC 600, the interconnects between filter 640 and balun 630 can be shrunk, which can reduce signal insertion loss and the addition of noise incurred in the transmission of the signals between filter 640 and balun 630, and improve bandwidth. In addition, balun 630 and filter 640 can be fabricated using the techniques described in FIGS. 1 through 5 to further reduce the size/footprint of IC 600 and signal insertion loss and noise. Further, as to be described below, more tightly integrating the balun with the filter can further improve the overall performance of the system while reducing the overall size/footprint of the system.

The operations of filter 640 and balun 630 may be explained in the context of certain examples. In a first example, filter 640 receives a single-ended input signal at one of terminals 650 or 660. Using one or more resonator devices 670, filter 640 filters the single-ended signal and outputs the filtered, single-ended signal to balun 630 via inductor 690. Balun 630 converts the filtered, single-ended signal to differential signals, which are outputted by balun 630 at terminals 610 and 620.

In a second example, filter 640 receives differential input signals at terminals 650 and 660 (e.g., a positive differential signal at terminal 650 and a negative differential signal at terminal 660) and provides filtered differential signals to balun 630 via inductor 690. Balun 630 coverts the filtered differential signals to a single-ended signal, which is outputted by balun 630 at either terminal 610 or 620, with the other one of terminal 610 or 620 being a reference terminal.

IC 600 may enable signal flow in the opposite direction, in which balun 630 converts a received signal, provides the converted signal to filter 640, and filter 640 performs a filtering operation on the converted signal. Such operations at balun 630 and filter 640 may be explained in the context of certain examples. In a third example, balun 630 receives differential signals at terminals 610 and 620 (e.g., a positive differential signal at terminal 610 and a negative differential signal at terminal 620) and provides a single-ended signal to filter 640 via inductor 690. Filter 640 filters the single-ended signal using one or more resonator devices 670 and provides a filtered, single-ended signal at one of terminals 650 or 660, with the other one of terminals 650 or 660 being a reference terminal.

In a fourth example, balun 630 receives a single-ended signal at one of the terminals 610 or 620, with the other one of terminals 610 or 620 being a reference terminal. Balun 630 converts the single-ended input signal to differential signals, which are provided to filter 640 via inductor 690. Using one or more resonator devices 670, filter 640 filters the differential signals and outputs filtered differential signals at terminals 650 and 660.

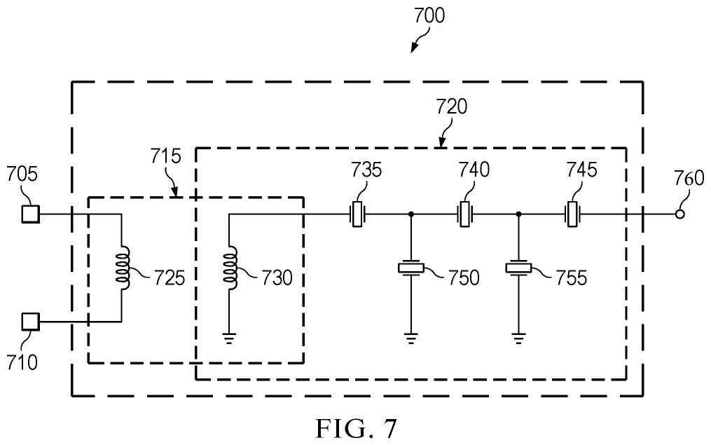

In some examples, IC 600 enables bidirectional signal flow through IC 600. For example, the same IC 600 may enable both the first and third examples above described with reference to FIG. 6. As another example, the same IC 600 may enable both the second and fourth examples described above with reference to FIG. 6. Additional examples of FIG. 6 including example arrangements of a balun 130 at least partially integrated with a filter 140, and example bidirectional operations of signal conversion and filtering, are explained further with reference to the IC schematics of FIGS. 7-9.

FIG. 7 is a schematic illustrating an IC 700 having a balun 715 and a filter 720, in which filter 720 has BAW resonators 735-755 arranged in a ladder-type configuration. In this example, balun 715 and filter 720 share at least one inductor 730. The integration of inductor 730 as a shared component for balun 715 and filter 720 may be implemented, for example, by forming respective portions of balun 715 and filter 720 within the same conductive layer of an IC, as disclosed above in describing the various examples shown in FIGS. 1 through 5.

As shown in FIG. 7, balun 715 has differential terminals 705 and 710, which can correspond to differential terminals 610 and 620 of FIG. 6. Balun 715 also includes a first inductor 725 coupled between terminals 705 and 710, and a second inductor 730 magnetically coupled to the first inductor 725. First inductor 725 and second inductor 730 can correspond to, respectively, first inductor 680 and second inductor 690 of FIG. 6. In some examples, differential terminals 705 and 710 can each be coupled to a power amplifier, or can be coupled to the differential outputs of a differential power amplifier. Terminal 705 can receive provide a positive differential 8 signal to balun 715, and terminal 710 can provide a negative differential signal to balun 715.

Filter 720 includes at least five BAW resonators 735, 740, 745, 750 and 755 arranged in a ladder-type configuration, inductor 730 (shared with balun 715) and a single-ended terminal 760. Inductor 730 is coupled in series to the single-ended terminal 760 along a serial path. Inductor 730 is further coupled in parallel to a ground terminal along first and second parallel paths. BAW resonators 735, 740 and 745 are coupled together in series along the serial path. BAW resonator 750 is coupled in parallel between BAW resonator 735 and 740 along the first parallel path. BAW resonator 755 is coupled in parallel between BAW resonator 740 and 745 along the second parallel path. Although filter 720 is illustrated as having five BAW resonators 735, 740, 745, 750 and 755, any suitable number of BA W resonators arranged in a ladder-type configuration may be used.

In operation, balun 715 can receive positive and negative differential signals from differential terminals 705 and 710, respectively, and can output a single-ended signal to filter 720. Such a signal conversion may be implemented, for example, by magnetically coupling inductor 730 to inductor 725 and by further coupling inductor 730 between a ground terminal and BAW resonator 735 of filter 720. Filter 720 can receive a single-ended input signal from balun 715, can filter the received input signal using BAW resonators 735-755, and can output a corresponding filtered single-ended signal at output terminal 760, which corresponds to terminal 650 of FIG. 6. Such a signal flow would enable differential-to-single-ended signal conversion and filtering.

In some examples, IC 700 may enable signal flow in the opposite direction, wherein terminal 760 operates as a single-ended input terminal at the front end, filter 720 provides a single-ended signal to balun 715, and balun 715 provides differential signals to terminals 705 and 710. For example, differential terminals 705 and 710 can be coupled to a receiver (e.g., a low noise amplifier) and transmit differential signals from balun 715 to the receiver. Such an alternative signal flow would enable single-ended-to-differential signal conversion and filtering. In some examples, IC 700 can provide bidirectional signal flow that enables both single-ended-to-differential conversion and filtering and differential-to-single-ended conversion and filtering.

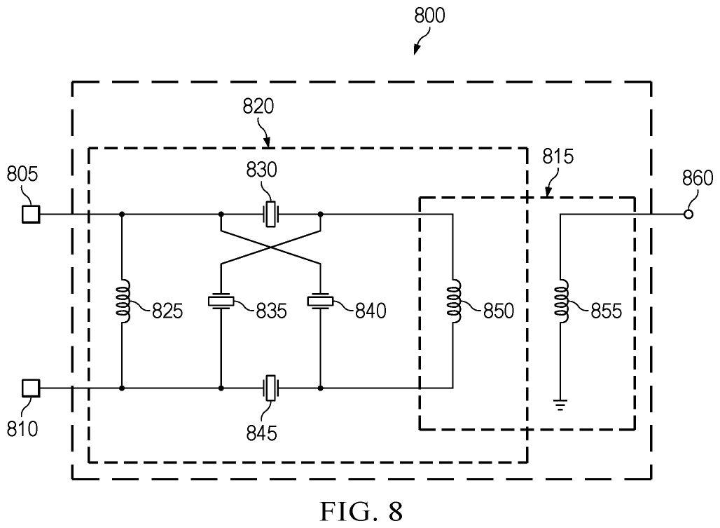

FIG. 8 is a schematic illustrating an example IC 800 having a balun 815 and a filter 820, in which filter 820 has BAW resonators 830-845 arranged in a lattice-type configuration. Balun 815 and filter 820 share at least one inductor 850. The integration of inductor 850 as a shared component of both filter 820 and balun 815 may be implemented, for example, by forming respective portions of filter 820 and balun 815 within the same conductive layer of an IC, as disclosed above in describing the various examples shown in FIGS. 1 through 5.

Filter 820 includes differential terminals 805 and 810, two inductors 825 and 850, and four BAW resonators 830, 835, 840 and 845 arranged in a lattice-type configuration. BAW resonators are 835 and 840 are each coupled between the terminals 805 and 810, BAW resonator 830 is coupled between terminal 805 and inductor, and BAW resonator 845 is coupled between terminal 810 and inductor 850. Although filter 820 uses four BAW resonators 830, 835, 840 and 845 for illustrative purposes, any suitable number of BAW resonators arranged in a lattice-type configuration may be used.

In some examples, differential terminals 805 and 810 can each be coupled to a power amplifier, or can coupled to the differential outputs of a differential power amplifier. Terminal 805 provides a positive differential signal to filter 820 and terminal 810 provides a negative differential signal to filter 820.

Balun 815 includes inductor 850 (shared with filter 820), a second inductor 855, and a single-ended terminal 860. Inductor 855 can be coupled between single-ended terminal 860 and a ground terminal. Inductors 850 and 855 are magnetically coupled to each other. Inductor 855 is coupled between the ground terminal and single-ended terminal 860. In some examples, the self-inductance of balun 815 can provide parallel inductance to the BAW resonators 825-845 of filter 820, which can broaden the bandwidth of filter 820.

In FIG. 8, terminal 860 can correspond to terminal 610 of FIG. 6, and terminal 620 of FIG. 6 can be coupled to ground. Inductor 855 can correspond to inductor 680 of FIG. 6, and inductor 850 can correspond to inductor 690 of FIG. 6. Terminals 805 and 810 can correspond to terminals 650 and 660.

In operation, filter 820 can receive differential signals from terminals 805 and 810 and provide differential filtered outputs to balun 815. Balun 815 can convert the filtered differential signals received from filter 820 and output a filtered, single-ended signal at terminal 860. Accordingly, such a signal flow would enable differential-to-single-ended signal conversion and filtering.

In some examples, IC 800 may enable signal flow in the opposite direction. For example, balun 815 can convert a single-ended signals received at terminal 860 to differential signals, which are both provided to filter 820 (e.g., at opposite ends of inductor 850). Upon receiving differential signals from balun 815, filter 820 can filter the differential signals and provide a respective filtered differential signal to differential terminals 805 and 810. Such signal flow would enable single-ended-to-differential signal conversion and filtering. In some examples, IC 800 can provide bidirectional signal flow that enables both single-ended-to-differential conversion and filtering and differential-to-single-ended conversion and filtering.

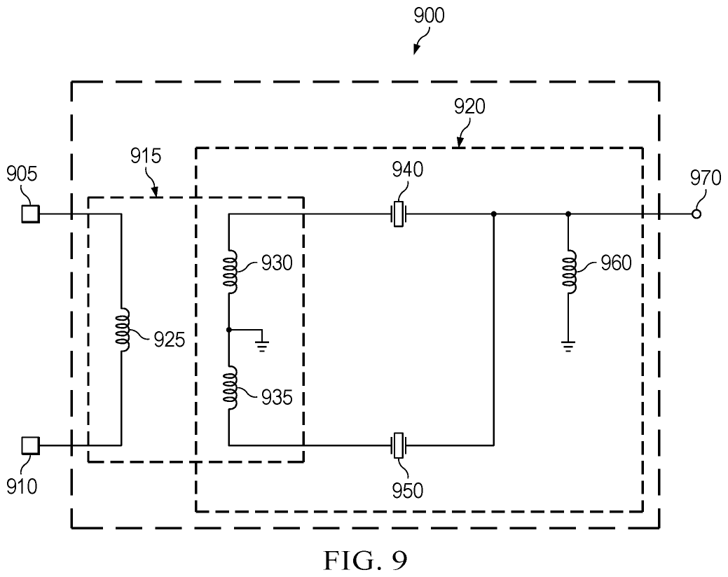

FIG. 9) is a schematic illustration of a portion of an IC 900 having a balun 915 integrated together with a filter 920, in which filter 920 has BAW resonators 940-950 arranged in a transversal-type configuration. Balun 915 and filter 920 share at least two inductors 930 and 935. The integration of inductors 930 and 934 as shared components of both filter 920 and balun 915 may be implemented, for example, by forming respective portions of filter 920 and balun 915 within the same conductive layer of an IC, as disclosed above in describing the various examples shown in FIGS. 1 through 5.

Balun 915 includes differential terminals 905 and 910, a first inductor 925 coupled between terminals 905 and 910, and second and third inductors 930 and 935 magnetically coupled to first inductor 925. In some examples, differential terminals 905 and 910 can each be coupled to a power amplifier or can be coupled to the differential outputs of a differential power amplifier. Terminal 905 provides a positive differential signal to balun 915 and terminal 910 provides a negative differential signal to balun 915.

Inductor 930 is coupled between a ground terminal and BAW resonator 940. Inductor 935 is coupled between the ground terminal and BAW resonator 950. The arrangement of a ground terminal between inductors 930 and 935, together with the magnetic coupling between inductor 925 and both inductors 930 and 935, enables balun 915 to provide a first signal to BAW resonator 940 and a second signal to the BAW resonator 950, wherein the second signal has a 180 degrees phase shift relative to the first signal.

The use of at least three inductors 925, 930, and 935 for balun 915, in which a ground terminal is coupled between or “center taps” inductors 930 and 935, provides balun 915 with a self-inductance. The self-inductance of balun 915 can reduce by half the inductance used for compensation of the static capacitance of the BAW resonators of filter 820, as compared to a balun that uses only a single shunt inductor. In some examples, reducing the inductance values of balun 915 results in reducing the corresponding number of respective coil windings of inductors 925, 930, and 935. Fewer coil windings can reduce the associated chip area, design complexity, and fabrication costs associated with balun 915. The center-tap arrangement of balun 915 also enables providing 180 degree phase shift to filter 920, in which the signal provided to BAW resonator 940 is phase shifted 180 degrees relative to the signal provided to BAW resonator 950.

In FIG. 9, terminals 905 and 910 can correspond to terminals 610 and 620 of FIG. 6, and inductor 925 can correspond to inductor 680 of FIG. 6. Also, inductor 930 can correspond inductor 690 of FIG. 6, and terminal 970 can correspond terminal 650, while terminal 660 is coupled to ground.

The coupling factor of between each of the inductors 925, 930, and 935 may be lower than one (100%). Among other considerations, the coupling factor may be affected, for example, by the conductive material used (e.g., copper or aluminum) for coil windings of each inductor 925, 930, and 935 and by how the coils are magnetically coupled together (e.g., in either a stacked or a coplanar arrangement).

In the absence of compensation, the degree to which a given coupling factor is less than one may impact the insertion loss of filter 140. However, modifying the respective inductance values of inductors 925, 930, and 935, such as by increasing or decreasing the number of coil windings for each, can at least partially compensate for imperfect coupling factors between each inductor 925, 930, and 935.

If it is desirable to approximate the insertion loss of a perfect coupling factor of 1, for example, then one way to achieve this is to determine the expected coupling factor between primary inductors 930 and 935 under a given design, and to then design secondary inductor 925 to compensate. In some examples, primary inductors 930 and 935 have a couple factor of 0.4 therebetween, and each has an inductance of 0.9 L, secondary inductor 925 has an inductance value of 1.7 L and a couple factor of 0.8 between inductor 925 and each of the primary inductors 930 and 935. In some examples, primary inductors 930 and 935 have couple factor of 0.4 therebetween, and each has an inductance or each 1.8 L, secondary inductor 925 has an inductance value of 1.9 L and a couple factor of 0.6 between inductor 925 and each of the primary inductors 930 and 935.

Filter 920 includes at least two inductors shared with balun 915, a third inductor 960 external to balun, two BAW resonators 940 and 950, and a single-ended output terminal 970. As shown in FIG. 9, BAW resonators 940 and 950 are arranged in a transversal-type configuration. Such an arrangement may be effected, for example, by coupling BAW resonator 940 between inductor 930 and an output terminal 970 and by coupling BAW resonator 950 between inductor 935 and the output terminal 970. Although filter 920 uses two BAW resonators 940 and 950 for illustrative purposes, any suitable number of BAW resonators arranged in a transversal-type configuration may be used. Inductor 960 is coupled between the ground terminal and output terminal 970.

In operation, terminal 970 provides a single-ended signal that has been converted by balun 915 and filtered by filter 920 relative to corresponding differential input signals received at terminals 905 and 910. Such a configuration would at least enable differential-to-single-ended conversion and filtering.

In some examples, IC 900 enables signal flow in the opposite direction. For example, terminals 905 and 910 may each provide positive and negative differential signals, respectively, which have been filtered by filter 920 and converted by balun 915 relative to a corresponding single-ended input signal received at terminal 970. Such signal flow would enable single-ended-to-differential conversion and filtering. In some examples, IC 900 can provide bidirectional signal flow that enables both single-ended-to-differential conversion and filtering and differential-to-single-ended conversion and filtering.

FIG. 10 is a graph illustrating comparative insertion loss as a function of quality factor Q for both a primary inductor 1010 and a secondary inductor 1020 of a balun (e.g., balun 130) according to some examples. The y-axis measures insertion loss in decibels and the x-axis is measures the corresponding quality factor in Q values. As shown in FIG. 10, while the primary inductor 1010 exhibits significant loss at lower Q values, the secondary inductor 1020 is not as sensitive. Accordingly, for certain examples that use a stacked arrangement of inductors for balun 130, it may be advantageous to use a copper layer to form the primary inductor(s), and that use of an aluminum layer for a secondary inductor may be acceptable due to the lower loss sensitivity of the secondary inductor.

The present disclosure describes various filter circuits, and methods of their manufacture, which provide the integration of a balun 130 together with a filter 140 on the same semiconductor die. While certain example examples describe balun 130 and filter 140 as being integrated in terms of having one or more inductor components in common, in various other examples the balun 130 and filter 140 may not have any internal components in common, while nevertheless being integrally formed within the same layer(s) on the same semiconductor die. In addition, certain features of various examples may be integrated together. For example, certain examples may use a filter 140 having BAW resonators arranged in any suitable combination of a ladder-type configuration, a lattice-type configuration, or a transversal-type configuration.

In this description, the term “couple” may cover connections, communications or signal paths that enable a functional relationship consistent with this description. For example, if device A provides a signal to control device B to perform an action, then: (a) in a first example, device A is directly coupled to device B; or (b) in a second example, device A is indirectly coupled to device B through intervening component C if intervening component C does not substantially alter the functional relationship between device A and device B, so device B is controlled by device A via the control signal provided by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. For example, a structure described herein as including one or more semiconductor elements (such as transistors), one or more passive elements (such as resistors, capacitors and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, such as by an end-user and/or a third party.

Certain components may be described herein as being of a particular process technology, but these components may be exchanged for components of other process technologies. Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in series or in parallel between the same two nodes as the single resistor or capacitor.

As used herein, the terms “terminal”, “node”, “interconnection”, “pin”, “ball”, “electrode” and “lead” are used interchangeably. Unless specifically stated to the contrary, these terms are generally used to mean an interconnection between or a terminus of a device element, a circuit element, an integrated circuit, a device or other electronics or semiconductor component. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board. The term “module” may be used to describe a circuit and/or an integrated circuit, or “module” may be used as a separately packaged circuit.

Uses of the phrase “ground voltage potential” and/or “ground” in this description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter, or, if the value is zero, a reasonable range of values around zero.

Modifications are possible in the described examples, and other examples are possible, within the scope of the claims.

What is claimed is:

1. An integrated circuit, comprising:
a filter having first and second filter terminals and including:
a first inductor coupled between the first and second filter terminals; and
a resonator coupled between the first and second filter terminals; and
a second inductor coupled between differential terminals, the second inductor magnetically coupled to the first inductor.

2. The integrated circuit of claim 1, wherein the first and second inductors are part of a balun.

3. The integrated circuit of claim 2, wherein:
the second filter terminal is coupled to a ground terminal;
the resonator is a first resonator;
the filter further includes a second resonator and a third resonator;
the first resonator is coupled between the first filter terminal and a first resonator terminal of the second resonator;
the third resonator is coupled between the first filter terminal and the first inductor; and
a second resonator terminal of the second resonator is coupled to the ground terminal.

4. The integrated circuit of claim 3, wherein:
the filter further includes a fourth resonator and a fifth resonator;
the third resonator is coupled between a third resonator terminal of the fourth resonator and the first resonator terminal;
the fifth resonator is coupled between the third resonator terminal and the first inductor; and
a fourth resonator terminal of the fourth resonator is coupled to the ground terminal.

5. The integrated circuit of claim 2, wherein:
the resonator is a first resonator;
the filter further includes a second resonator;
the first resonator is coupled between the first filter terminal and a first inductor terminal of the first inductor; and
the second resonator is coupled between the second filter terminal and a second inductor terminal of the first inductor.

6. The integrated circuit of claim 5, wherein:
the filter further includes a third resonator and a fourth resonator;
the third resonator is coupled between the first inductor terminal and the second filter terminal; and
the fourth resonator is coupled between the second inductor terminal and the first filter terminal.

7. The integrated circuit of claim 6, wherein the filter further includes a third inductor coupled between the first and second filter terminals.

8. The integrated circuit of claim 5, wherein one of the differential terminals is coupled to a ground terminal.

9. The integrated circuit of claim 2, wherein:
the resonator is a first resonator;
the filter further includes a second resonator and a third inductor, the third inductor coupled between the first and second filter terminals, and third inductor is magnetically coupled to the second inductor;
the second filter terminal is coupled to a ground terminal;
the first resonator is coupled between the first filter terminal and the second inductor; and
the second resonator is coupled between the first filter terminal and the third inductor.

10. The integrated circuit of claim 9, further comprising a fourth inductor coupled between the first filter terminal and the ground terminal.

11. The integrated circuit of claim 1, wherein the resonator includes a bulk acoustic wave (BAW) resonator.

12. The integrated circuit of claim 1, further comprising a semiconductor die including a first metal layer, an insulation layer, and a second metal layer, wherein:
the first metal layer is between the insulation layer and the semiconductor die;
the insulation layer is between the first metal layer and the second metal layer;
the first metal layer includes the resonator and the first and second filter terminals; and
the second metal layer includes the second inductor.

13. The integrated circuit of claim 12, wherein:
the second metal layer includes the first inductor.

14. The integrated circuit of claim 12, wherein:
the first metal layer includes the first inductor.

15. An integrated circuit, comprising:
a semiconductor die including a resonator;
a first metal layer on the semiconductor die, the first metal layer including a terminal of the resonator; and
a second metal layer on the first metal layer, the second metal layer including an inductor.

16. The integrated circuit of claim 15, further comprising an insulation layer between the first and second metal layers.

17. The integrated circuit of claim 15, wherein:
the inductor is a first inductor of a balun;
the second metal layer further includes a second inductor of the balun; and
the first inductor is magnetically coupled to the second inductor.

18. The integrated circuit of claim 15, wherein:
the inductor is a first inductor of a balun;
the first metal layer further includes a second inductor of the balun; and
the first inductor is magnetically coupled to the second inductor.

19. The integrated circuit of claim 15, wherein:
the resonator is part of a filter;
the inductor is a first inductor of a balun;
the first metal layer or the second metal layer includes a second inductor of the balun; and
the second inductor is also part of the filter.

20. The integrated circuit of claim 15, wherein the first metal layer includes aluminum.

21. The integrated circuit of claim 15, wherein the second metal layer includes copper.

22. The integrated circuit of claim 15, wherein the resonator includes a bulk acoustic wave (BAW) resonator.

23. An integrated circuit, comprising:
a first semiconductor die having a first surface;
a second semiconductor die having a second surface facing the first surface; and
a metal layer on the first surface and including:
an inductor, and
metal interconnects coupled between the first surface and the second surface.

24. The integrated circuit of claim 23, wherein:
the inductor is a first inductor of a balun; and
the metal layer further includes a second inductor of the balun.

25. The integrated circuit of claim 23, wherein:
the metal layer is a first metal layer;
the integrated circuit further includes a second metal layer between the first metal layer and the first surface;
the inductor is a first inductor of a balun; and
the second metal layer includes a second inductor of the balun.

26. The integrated circuit of claim 25, wherein the second metal layer includes aluminum.

27. The integrated circuit of claim 25, wherein the second metal layer includes a terminal of a resonator.

28. The integrated circuit of claim 27, wherein the resonator includes a bulk acoustic wave (BAW) resonator.

29. The integrated circuit of claim 27, wherein:
the resonator is part of a filter;
the second metal layer includes a terminal of the filter; and
the first inductor is a shared component of the filter and the balun.

30. The integrated circuit of claim 23, wherein the metal layer includes copper.
